(19) United States
(12) Patent Application Publication
(10) Pub. No.: US 2013/0077796 A1
(43) Pub. Date: Mar. 28, 2013

(54) Thermal Protection for Loudspeakers

(71) Applicants: Lars Risbo, Hvalsoe (DK); Milind Anil Borkar, Dallas, TX (US); Theis Buchwald Christiansen, Kobenhavn N (DK); Wendyam Fernand David Traore, Sachse, TX (US)

(72) Inventors: Lars Risbo, Hvalsoe (DK); Milind Anil Borkar, Dallas, TX (US); Theis Buchwald Christiansen, Kobenhavn N (DK); Wendyam Fernand David Traore, Sachse, TX (US)

(73) Assignee: TEXAS INSTRUMENTS INCORPORATED, Dallas, TX (US)

(21) Appl. No.: 13/247,569

(22) Filed: Sep. 28, 2011

(51) Int. Cl. H03G 11/00

(52) U.S. Cl. 381/55

(57) ABSTRACT

In an embodiment of the invention, the voice coil of an electro dynamic transducer is protected by measuring the power of the input audio signal. When a predetermined power limit is reached by the input audio signal, the power of the input audio signal is reduced.

### CROSS-REFERENCED TO RELATED APPLICATIONS

This application is related to Ser. No. ______/______ (TI-71350) entitled “Thermal Control of Voice Coils in Loudspeakers”, and to Ser. No. ______/______ (TI-70802) entitled “Over-excursion Protection for Loudspeakers”, filed on even date herewith and are hereby incorporated by reference for all that is disclosed therein.

### BACKGROUND

Loudspeakers used in compact and portable devices require significant design compromises that may lead to suboptimal sound quality and loudness. A loudspeaker used in a compact device (e.g. a cellular phone, an electronic tablet, a laptop computer, a PDA (personal digital assistant), a media player etc.) is usually small. As a result, the sensitivity of the loudspeaker can be low and the diaphragm on the loudspeaker can have a limited range of motion. Often loudspeakers are overdriven in order to obtain the loudness needed to hear the audio signal coming from it.

Overdriving a loudspeaker can cause the voice coil in a loudspeaker to overheat because of the additional current needed to overdrive the speaker. Overheating the loudspeaker can cause permanent damage to a loudspeaker. For example, overheating can change the shape of the diaphragm of the loudspeaker. A loudspeaker where the diaphragm has changed shape from its original form distorts sound coming from the loudspeaker.

In addition to changing the shape of the diaphragm, overheating a voice coil can cause the glue holding the voice coil to the driver to melt. When the glue melts it can cause the voice coil to separate from the driver rending the loudspeaker inoperable. Overheating the voice coil can also cause the solder connecting an amplifier to the voice coil to melt, disconnecting the loudspeaker from the amplifier. The heat from the voice coil can also cause the insulation on the voice coil to melt. When the insulation melts, the metal in the voice coil can short to each other reducing the number of windings in the voice coil. Reducing the number of windings in the coil can limit the loudness of the loudspeaker and further heat the voice coil due to the lowered resistance.

Overdriving a loudspeaker can increase the mechanical stress on the loudspeaker causing it to fail. Loudspeakers used in compact devices are relatively cheap. However, damage to a loudspeaker in a compact device may cause a return of the entire device. In order to reduce the damage done to loudspeakers and improve the loudness and quality of the loudspeakers, the power applied to a loudspeaker needs to be controlled to reduce overheating of the voice coil.

### BRIEF DESCRIPTION OF THE DRAWINGS

FIG. 1 is a cross-sectional view of an electro dynamic transducer (Prior Art).

FIG. 2 is a block diagram of an embodiment of a thermal protection system used to protect an electro dynamic transducer.

FIG. 3 is a flow diagram of an embodiment of a method of protecting a voice coil in an electro dynamic transducer from over heating.

FIG. 4 is a schematic illustrating how the resistance of a voice coil in an electro dynamic transducer may be measured dynamically.

FIG. 5 is a block diagram of an embodiment of a thermal protection system used to protect an electro dynamic transducer.

FIG. 6 is a block diagram of an embodiment of a thermal protection system used to protect an electro dynamic transducer.

### DETAILED DESCRIPTION

The drawings and description, in general, disclose a method for protecting an electro dynamic transducer (e.g. loudspeaker) against thermal overload. As part of the method, an estimate of the temperature of the voice coil in the electro dynamic transducer is obtained while the power of an input audio signal is measured. After the estimate of the temperature is obtained and the power of the input audio signal is measured, the power of the audio input signal is reduced when a power limit is exceeded and/or a temperature limit is exceeded.

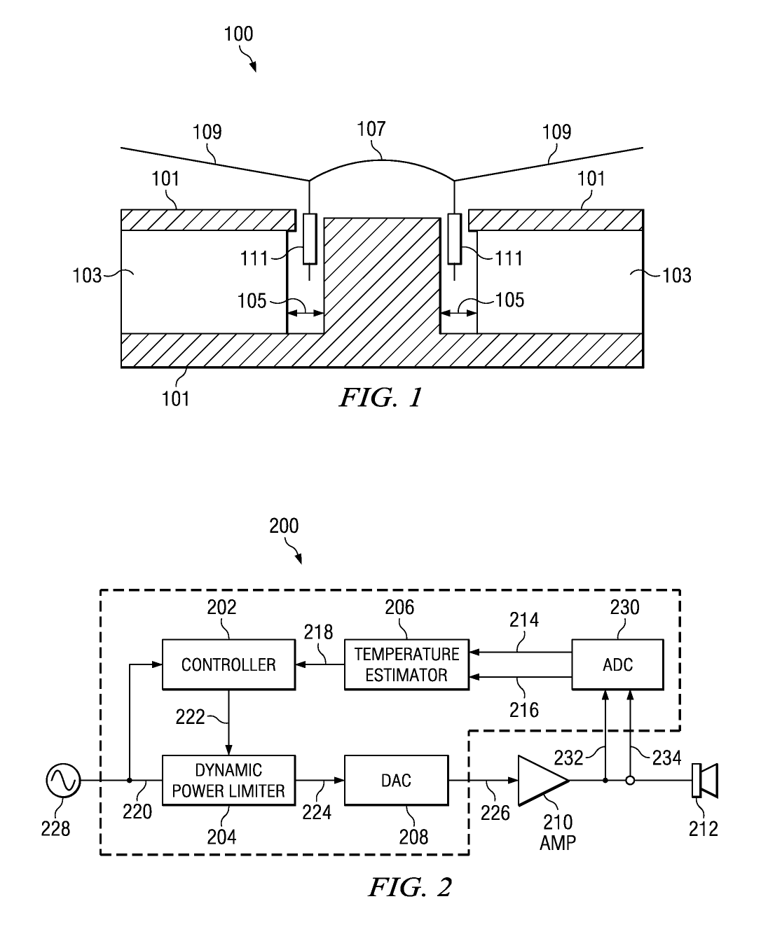

FIG. 1 is a cross-sectional view of an electro dynamic transducer 100 (Prior Art). The electro dynamic transducer may be used in a cellular phone, an electronic tablet, a laptop computer, a desktop computer, a television, a monitor, a portable radio, a portable musical playback system, a PDA and a media player. In this example of an electro dynamic transducer 100, the voice coil 111 is located in the magnetic field of the magnetic gap 105. The voice coil 111 is physically attached to the dome 107 of the electro dynamic transducer 100. A cone 109 is attached to the dome 107 of the electro dynamic transducer 100. The magnet 103 and the magnetic circuit 101 provide a magnetic field for the voice coil 111. The suspension and frame of the electro dynamic transducer is not shown is this example.

The voice coil 111 provides the motive to the cone 109 by the reaction of the magnetic field provided by the magnet 103 and the magnetic circuit 101 to the current flowing through the voice coil 111. By driving a current through the voice coil 111, a magnetic field is produced. This magnetic field causes the voice coil 111 to react to the magnetic field from the permanent magnet 103 fixed to the speaker's frame (not shown), thereby moving the cone 109 of the electro dynamic transducer 100. By applying an audio signal to the voice coil 111, the cone 109 will reproduce the sound pressure waves corresponding to the original audio signal.

The amount of power that a voice coil 111 may handle without damage is related to the thermal tolerance of the wire insulation, adhesive, and bobbin material, and may be influenced by the voice coil's position within the magnetic gap 105. In addition, the amount of power that a voice coil may use is limited by the amount of heat that can be removed from the voice coil 111.

FIG. 6 is a block diagram of an embodiment of a thermal protection system 600 used to protect an electro dynamic transducer 212. The protection system 600 comprises a controller 202, a dynamic power limiter 204 and a DAC (digital to analog converter) 208. The thermal protection system 600 along with the amplifier 210 may be integrated on a single integrated circuit. In this example, the controller 202 and the dynamic power limiter 204 are digital circuits. As consequence, the input audio signal 220 is a digital signal.

An input audio signal 220 is applied to the controller 202 and the dynamic power limiter 204. The controller 202 measures the power of the input audio signal 220. When the power of the input audio signal 220 exceeds a predetermined power limit in the controller 202, the controller 202 instructs the dynamic power limiter 204 to attenuate the input audio signal 220. The predetermined power limit is obtained by measuring the heating of the voice coil 111 while varying the amount of power in the input audio signal 220. The dynamic power limiter 204, for example, can attenuate the input audio signal 220 by multiplying the input audio signal by factor of X where X ranges from 0 to 1.

The attenuated input audio signal 224 is then applied to the DAC 208. The DAC 208 converts the digital attenuated input audio signal 224 to an analog signal 226. The analog signal 226 then drives the power amplifier 210. The gain of the amplifier 210 in this example is G. Since the gain of the input 226 to the amplifier 210 can vary from 0 to 1, the gain of the output of the amplifier 210 can vary from 0 to G.

Because the analog signal 226 is attenuated, the output 216 of the power amplifier 210 supplies a smaller current to the voice coil 111 of the electro dynamic transducer 212 than would have been supplied if the input audio signal 220 would not have been attenuated. Because a smaller current is supplied, the heating of the voice coil 111 is reduced.

In the embodiment shown in FIG. 6, when the power of the input audio signal 220 does not exceed a predetermined power limit in the controller 202, the controller 202 instructs the dynamic power limiter 204 to allow the input audio signal 220 to pass unchanged.

FIG. 2 is a block diagram of an embodiment of a thermal protection system 200 used to protect an electro dynamic transducer 212. The protection system 200 comprises a ADC 230, a temperature estimator 206, a controller 202, a dynamic power limiter 204 and a DAC (digital to analog converter) 208. The thermal protection system 200 along with the amplifier 210 may be integrated on a single integrated circuit. In this example, the temperature estimator 206, the controller 202 and the dynamic power limiter 204 are digital circuits. As consequence, the input audio signal 220 is a digital signal.

In an embodiment of the invention, a voltage 232 across the voice coil 111 of the electro dynamic transducer 212 and an estimate of the current 234 through the voice coil 111 are presented to the ADC 230. The outputs 214 and 216 of the ADC 230 are applied to the temperature estimator 206. Based on the voltage 216 and the current 214, the temperature estimator 206 outputs an estimate 218 of the temperature of the voice coil 111. The temperature estimate 218 may be calculated in several ways.

The temperature of the voice coil 111 may be estimated by measuring a the resistance of the voice coil 111. The resistance or dcr (direct current resistance) of voice coils typically range from 4 ohms to 16 ohms at room temperature, 73° F. However, as the temperature of a voice coil 111 increases due to current being conducted through it, the resistance of the voice coil 111 also increases. The resistance of a voice coil 111 in an electro dynamic transducer 212 at particular temperatures may be measured and cataloged. The results of these measurements may be included as part of a lookup table used in the temperature estimator 206. The temperature estimator 206 may also use an equation based on these measurements to give the temperature estimate 218.

The temperature estimate 218 is applied to the controller 202. In addition to the temperature estimate 218, an input audio signal 220 is applied to the controller 202. The controller 202 uses the temperature estimate 218 and the input audio signal 220 to dynamically control the gain of the dynamic power limiter 204. For example, when the power of the input audio signal 220 exceeds a predetermined power limit in the controller 202, the controller 202 instructs the dynamic power limiter 204 to attenuate the input audio signal 220. The dynamic power limiter 204, for example, can attenuate the input audio signal 220 by multiplying the input audio signal by factor of X where X ranges from 0 to 1.

The attenuated input audio signal 224 is then applied to the DAC 208. The DAC 208 converts the digital attenuated input audio signal 224 to an analog signal 226. The analog signal 226 then drives the power amplifier 210. The gain of the amplifier 210 is G. Since the gain of the input 226 to the amplifier 210 can vary from 0 to 1, the gain of the output of the amplifier 210 can vary from 0 to G.

Because the analog signal 226 is attenuated, the output 216 of the power amplifier 210 supplies a smaller current to the voice coil 111 of the electro dynamic transducer 212 than would have been supplied if the input audio signal 220 would not have been attenuated. Because a smaller current is supplied, the heating of the voice coil 111 is reduced.

In the previous example, the current supplied to the voice coil 111 was reduced. Because the current supplied to the voice coil 111 was reduced, the loudness of the electro dynamic transducer 212 would not be as loud as it would have been otherwise. However, because the current may only be limited for a short time, the perceived loudness of the electro dynamic transducer 212 does not change appreciably when compared to the case were the current is not reduced. The controller 202 dynamically changes in response to the power of the input audio signal 220 and the temperature estimate 218.

When neither a input signal power limit nor a temperature limit is exceeded, the controller 202 instructs the dynamic power limiter 204 to allow the input signal 220 to pass through the dynamic power limiter 204 without attenuation. As consequence, the loudness produced by this signal in the electro dynamic transducer 212 remains unchanged as well.

In the case where a temperature limit is exceeded and the input signal power limit is not exceeded, the controller 202 instructs the dynamic power limiter 204 to attenuate the input audio signal 220. The amount the input audio signal 220 is attenuated by the dynamic power limiter 204 when the temperature limit is exceeded and the input signal power limit is not exceeded is different from the amount the input audio signal 220 is attenuated when the temperature limit is exceeded and the input signal power limit is exceeded. The controller 202 adjusts the amount the input signal 220 is attenuated based on whether both the input signal power limit and the temperature limit are exceeded. In addition, the absolute value of the signal power limit and the absolute value of the temperature limit determine the amount of attenuation of the input audio signal 220.

In an embodiment of the invention, the controller 202 may be a PID (proportional integral derivative) controller. A PID controller is a generic control loop feedback mechanism widely used in industrial control systems. A PID controller calculates an “error” value as the difference between a measured process variable (e.g. temperature or power) and a desired set point for the variable. The controller attempts to minimize the error by adjusting the process control inputs.

The PID controller calculation involves three separate constant parameters, and is accordingly sometimes called three term control: the proportional, the integral and the derivative values. These values can be interpreted in terms of time: P depends on the present error, I on the accumulation of past errors, and D is a prediction of future errors, based on current rate of change. The weighted sum of these three actions is used to adjust the process via a control element such as the temperature of a voice coil.

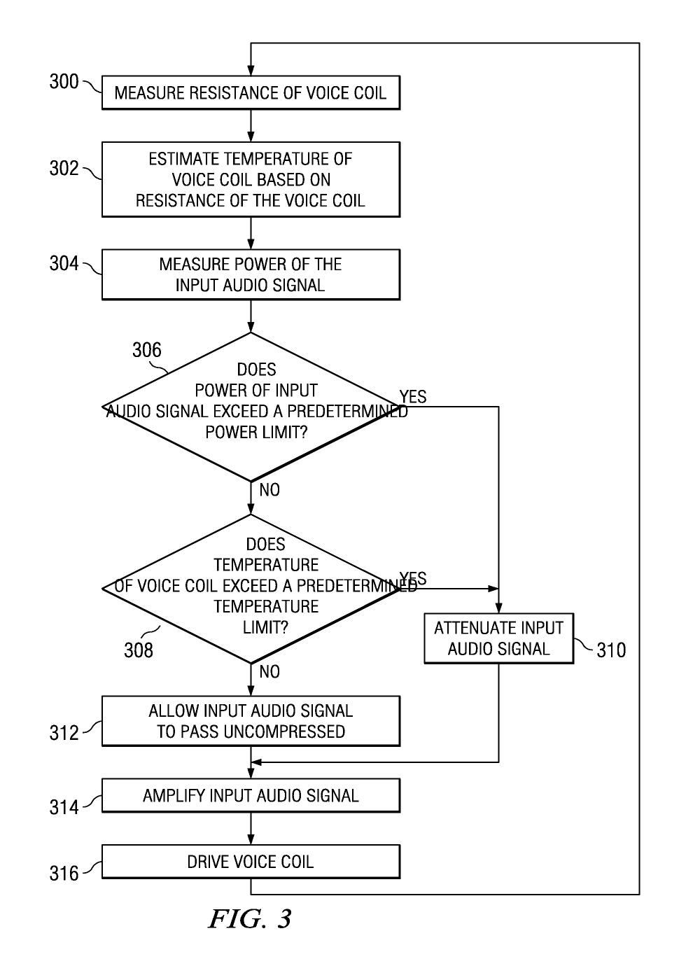

FIG. 3 is a flow diagram of an embodiment of a method of protecting a voice coil in an electro dynamic transducer from overheating. During step 300, the resistance due to heating of the voice coil 111 is measured. After measuring the resistance due to heating of the voice coil 111, an estimate of the temperature of voice coil 111 is made during step 302. The estimate of the temperature can be made using a lookup table or an equation that are based on measured resistances of the voice coil at different temperatures.

During step 304, the power of an input audio signal 220 is measured. During step 306, it is determined whether the measured power of the input audio signal 220 exceeds a predetermined power limit. When the measured power of the input audio signal 220 exceeds the predetermined power limit, the input audio signal 220 is attenuated as shown in step 310. When the measured power of the input audio signal 220 does not exceed the predetermined power limit, it is determined during step 308 if the temperature of the voice coil 111 exceeds a predetermined temperature limit. When the temperature of the voice coil 111 exceeds the predetermined temperature limit, the input audio signal is attenuated as shown in step 310.

When the temperature of the voice coil 111 does not exceed the predetermined temperature limit, the input audio signal is not attenuated and is passed directly to an amplifier to be amplified as shown in step 312. The amplifier, as shown in step 314, then amplifies the input audio signal. Next the amplifier drives the voice coil 111. The attenuated signal from step 310 is also amplified in step 314 when a power limit or a temperature limit is exceeded.

The process shown in FIG. 3 continues to monitor the temperature of the voice coil and monitor the power of the input audio signal 220 in order to prevent the voice coil from overheating. The power limit and the temperature limit may be set such that perceived loudness of the sound produced by the electro dynamic transducer 212 is nearly the same as when the input audio signal is not attenuated.

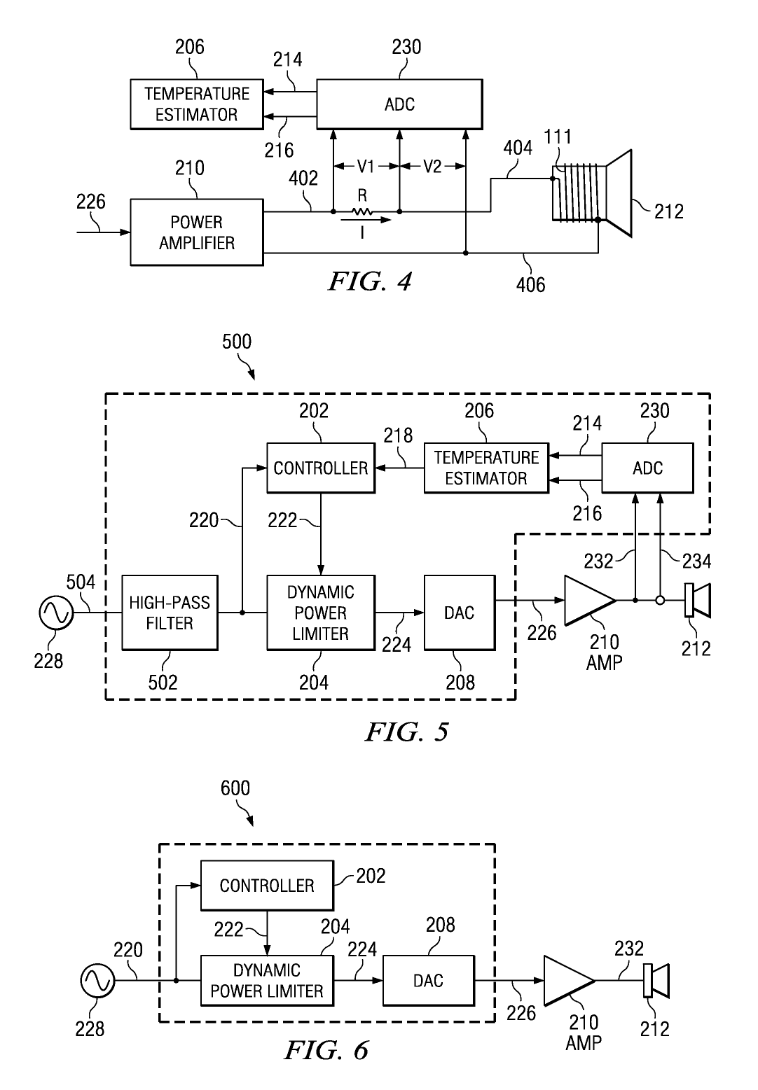

FIG. 4 is a schematic illustrating how the resistance of a voice coil in an electro dynamic transducer may be calculated dynamically. A resistor R is electrically connected in series between the power amplifier 210 and the voice coil 111 of the electro dynamic transducer 212. In this example, the instantaneous analog voltages V1 and V2 are input to an ADC (analog-to-digital converter) 230. The ADC 230 then outputs digital values 214 and 216 to the temperature estimator 206 representing the instantaneous analog voltages V1 and V2 respectively. The instantaneous current I drawn by the electro dynamic transducer 212 may be calculated by dividing the voltage V1 between node 402 and 404 by the resistance of resistor R. After obtaining the instantaneous current I, the instantaneous resistance of the voice coil 111 may be calculated by dividing the instantaneous voltage V2 between nodes 406 and 404 by the instantaneous current I.

The instantaneous temperature of the voice coil 111 may be estimated by applying the instantaneous resistance of the voice coil 111 to a lookup table or an equation contained in the temperature estimator 206. The values used in the lookup table or in the equation are obtained by measuring the resistance of the voice coil at different temperatures prior to using the temperature estimator.

In another embodiment of the invention, the instantaneous current conducted through the voice coil 111 may be determined using a current sensor. A current sensor is a device that detects electrical current (AC or DC) in a wire, and generates a signal proportional to it. The generated signal can be an analog voltage, an analog current or a digital output. The generated signal along with the voltage across the voice coil can then be used to calculate the instantaneous resistance of the voice coil. The instantaneous temperature of the voice coil 111 may be estimated by applying the instantaneous resistance of the voice coil 111 to a lookup table or an equation.

In another embodiment of the invention, the current sensing is part of (built into) the amplifier 210. In this embodiment, the current drawn through the coil 111 may be calculated by measuring the voltage drop across the output transistors of the amplifier 210. The amplifier 210 in this example is a class D amplifier. However, other types of amplifiers such as class A or class AB could be used.

FIG. 5 is a block diagram of an embodiment of a thermal protection system 500 used to protect an electro dynamic transducer 212. The protection system 500 comprises an ADC 230, a temperature estimator 206, a controller 202, a dynamic power limiter 204, high-pass filter 520 and a DAC (digital to analog converter) 208. The protection system 500 shown in FIG. 5 is the same as the protection system 200 shown in FIG. 2 except for the addition of a high-pass filter 502 placed at the input of the protection system 500.

In the embodiment of the invention shown in FIG. 5, the high-pass filter 502 is added to remove low frequency signals that can not be reproduced by an electro dynamic transducer 212. For example, an electro dynamic transducer 212 located in a cell phone may not be able to reproduce frequencies below 200 Hz. Removing the frequencies below 200 Hz in the input audio signal 504, reduces distortion in the electro dynamic transducer 212. In addition, low frequency signals require more power to be reproduced than high frequency signals.

Because low frequency signals require more power to be reproduced, the current needed to drive the voice coil 111 is reduced when low frequency signals are removed from the input audio signal 504. Reducing the amount of current needed to drive the voice coil 111 also reduces the heating of the coil. Therefore, removing low frequency signals from the input audio signal helps protect the electro dynamic transducer 212 from overheating.

The foregoing description has been presented for purposes of illustration and description. It is not intended to be exhaustive or to limit the invention to the precise form disclosed, and other modifications and variations may be possible in light of the above teachings. The embodiments were chosen and described in order to best explain the applicable principles and their practical application to thereby enable others skilled in the art to best utilize various embodiments and various modifications as are suited to the particular use contemplated. It is intended that the appended claims be construed to include other alternative embodiments except insofar as limited by the prior art.

What is claimed is:

1. A method for protecting an electro dynamic transducer against thermal overload of a voice coil comprised in the transducer, comprising:
measuring the power of an input audio signal wherein the input audio signal drives an amplifier and wherein an output of the amplifier is electrically connected to the voice coil;
reducing the power of the input audio signal when a predetermined input audio signal power limit is reached.

2. The method of claim 1 wherein reducing the power of the input audio signal when a predetermined input audio signal power limit is reached comprises:
attenuating the input audio signal by a factor of X, wherein X may have any value in the range of 0 to 1.

3. The method of claim 2 wherein the output voltage of the amplifier is approximately equal to G*X*VIN wherein G is the fixed gain of the amplifier and VIN is the voltage of a signal presented at an input of the amplifier.

4. The method of claim 1 wherein the input audio signal is passed through a high-pass filter before the power of the input audio signal is measured.

5. A method for protecting an electro dynamic transducer against thermal overload of a voice coil comprised in the transducer, comprising:
estimating the temperature of the voice coil;
measuring the power of an input audio signal wherein the input audio signal drives an amplifier and wherein an output of the amplifier is electrically connected to the voice coil;
reducing the power of the input audio signal when a predetermined input audio signal power limit is not reached and a voice coil temperature limit is reached.

6. The method of claim 5 wherein estimating the temperature of the voice coil comprises:
measuring a resistance of the voice coil due to heating of the voice coil.

7. The method of claim 5 wherein estimating the temperature of the voice coil comprises:
measuring a first voltage across a resistor wherein the resistor is in series with the voice coil;
measuring a second voltage across the voice coil;
applying the voltages to a temperature estimator wherein the temperature estimator outputs the temperature based on the applied voltages.

8. The method of claim 7 wherein the temperature estimator estimates the temperature using a look-up table, wherein the look-up table is based on measured data that correlates the temperature of voice coil with the resistance of the voice coil.

9. The method of claim 7 wherein the temperature estimator estimates the temperature using a formula, wherein the formula uses measured data that correlates the temperature of the voice coil with the resistance of the voice coil.

10. The method of claim 5 wherein reducing the power of the input audio signal when a predetermined input audio signal power limit is reached comprises:
attenuating the input audio signal by a factor of X, wherein X may have any value in the range of 0 to 1.

11. The method of claim 10 wherein the output voltage of the amplifier is approximately equal to G*X*VIN wherein G is the fixed gain of the amplifier and VIN is the voltage of a signal presented at an input of the amplifier.

12. The method of claim 5 wherein the input audio signal is passed through a high-pass filter before the power of the input audio signal is measured.

13. An apparatus comprising:
an electro dynamic transducer, the electro dynamic transducer comprising a voice coil;
an amplifier; the amplifier having an input and an output wherein the voice coil is electrically connected to the output of the power amplifier;
a DAC having an output and an input wherein the output of the DAC is electrically connected to the input of the power amplifier;
a dynamic power limiter; the dynamic power limiter having two inputs and an output, the output electrically connected to the input of the DAC;
an ADC having inputs and outputs wherein a first analog voltage and a second analog voltage are presented at the inputs of the ADC wherein the first analog voltage is an instantaneous voltage across the voice coil and the second analog voltage is an instantaneous voltage across a resistor wherein the resistor is in series with the voice coil wherein a first output from the ADC is a digital representation of the first analog voltage and wherein a second output from the ADC is a digital representation of the second analog voltage;
a temperature estimator, the temperature estimator having inputs and an output wherein the first and second outputs from the ADC are electrically connected to the inputs of the temperature estimator wherein the output of the temperature estimator outputs a digital value representing a temperature of voice coil;
a controller, the controller having two inputs and an output wherein a first input is electrically connected to the output of the temperature estimator and the output of the controller is electrically connected to a first input of the dynamic power limiter;
wherein a first digital audio signal is electrically connected to a second input of the controller and to a second input of the dynamic power limiter;
wherein when the power of the first digital audio signal is equal to or greater than a predetermined power value, the dynamic power limiter reduces the power of a second digital audio applied to the input of the DAC such that an analog signal applied to the input of the power amplifier is attenuated.

14. The apparatus of claim 13 wherein when the output of temperature estimator is equal to or greater than a predetermined temperature value and the power of the first digital audio signal is lower than the predetermined power value, the dynamic power limiter reduces the power of the second digital audio signal applied to the input of the DAC.

15. The apparatus of claim 13 wherein when the output of temperature estimator is less than the predetermined temperature value and the power of the first digital audio signal is less than a predetermined power value, the dynamic power limiter does not change the power of the digital audio applied to the input of the DAC.

16. The apparatus of claim 13 wherein when the output of temperature estimator is less than a predetermined temperature value and the power of the first digital audio signal is equal to or greater than the predetermined power value, the dynamic power limiter reduces the power of the second digital audio signal applied to the input of the DAC.

17. The apparatus of claim 13 wherein the apparatus is an electronic device selected from a group consisting of a cellular phone, an electronic tablet, a laptop computer, a desktop computer, a television, a monitor, a portable radio, a portable musical playback system, a PDA and a media player.

18. The apparatus of claim 13 wherein the temperature estimator, the controller and the dynamic power limiter are digital circuits.

19. The apparatus of claim 13 wherein the controller is a PID (proportional integral derivative) controller.

20. The apparatus of claim 13 wherein the temperature estimator, the controller and the dynamic power limiter, the DAC and the amplifier are integrated on a single integrated circuit.
